(19) United States
(12) Patent Application Publication
(10) Pub. No.: US 2024/0304412 A1
(43) Pub. Date: Sep. 12, 2024

(54) PARTICLE BEAM MICROSCOPE

(71) Applicant: Carl Zeiss Microscopy GmbH, Jena (DE)

(72) Inventor: Erik Essers, Aalen (DE)

(21) Appl. No.: 18/600,289

(22) Filed: Mar. 8, 2024

(30) Foreign Application Priority Data
Mar. 10, 2023 (DE) 10 2023 106 029.5

(51) Int. Cl. H01J 37/28; H01J 37/147

(52) U.S. Cl. CPC H01J 37/28; H01J 37/147; H01J 2237/2443

(57) ABSTRACT

A particle beam microscope comprises a particle beam source, an objective lens, a first scintillator, a second scintillator, and a light detector. A first beam path of light generated by the first scintillator and a second beam path of light generated by the second scintillator overlap one another. A scintillator body of the first scintillator generates light having a first spectral distribution. The second scintillator generates light having a second spectral distribution, which is different from the first spectral distribution.

### CROSS-REFERENCE TO RELATED APPLICATION

This application claims benefit under 35 U.S.C. § 119 to German Application No. 10 2023 106 029.5, filed Mar. 10, 2023. The entire disclosure of this application is incorporated by reference herein.

### FIELD

The present disclosure relates to a particle beam microscope, such as a particle beam microscope comprising a particle beam source, an objective lens, a scintillator and a light detector. The particle beam source generates a particle beam by generating and accelerating charged particles, such as electrons or ions, and shaping them into a particle beam. The objective lens focuses this particle beam on the surface of an object to form a small beam spot. The particles of the particle beam that impinge on the object interact with the object, wherein the type and extent of the interaction depend on the properties of the object at the particle beam incidence location. The scintillator and the light detector form a detection system for particles generated on account of the interaction at the object. On the basis of the detection of these particles, it is possible to obtain information concerning the properties of the object, such as, for instance, structure and chemical composition. The detected particles include electrons which are generated near the surface of the object as a result of the incidence of the particles of the particle beam and emerge from the object. These electrons have greatly varying directions and kinetic energies as they emerge from the object. The kinetic energies range from a few electronvolts up to the kinetic energy of the particles in the incident particle beam, which may be several kiloelectronvolts, depending on the application.

### BACKGROUND

Electrons emerging from an object impinge on a scintillator, which is configured to generate light if an electron impinges on the scintillator or penetrates into the latter. The intensity of the generated light increases with the intensity of the electrons impinging on the scintillator. Part of the light generated by the scintillator is detected by the light detector and converted into electrical detection signals, which can be read in and analysed by a controller of the particle beam microscope. The intensity of the detected light represents the intensity of the electrons that are generated by the particle beam at the object and emerge from the latter and may yield valuable information concerning the properties of the object at the particle beam incidence location.

Besides the intensity of the electrons generated at the object, their kinetic energy and the direction in which detected electrons emerged from the object can also be of interest in order to acquire information concerning the properties of the object. For this purpose, it is conventional practice to use energy filters, for example, which select the electrons that arise at the object before their detection with regard to their kinetic energy in order to be able to determine the intensity of the generated electrons depending on the kinetic energy thereof. Particle beam microscopes are known which comprise a plurality of different detectors configured to selectively detect different types of electrons generated at the object. The different detectors differ from one another substantially in terms of their spatial positioning in the particle beam microscope.

### SUMMARY

It is not easy to integrate a plurality of electron detectors into a particle beam microscope at different spatial positions, since the installation space available for detectors and for the leads used for the operation of the detectors is limited.

The present disclosure proposes a particle beam microscope comprising one or more detectors by which electrons are selectively detectable with regard to their kinetic energy and/or direction as they emerge from the object.

According to an aspect of the disclosure, a particle beam microscope comprises a particle beam source for generating a particle beam, an objective lens for focusing the particle beam in an object plane, at least one scintillator configured to generate light from electrons arriving from the object, and at least one light detector configured to detect the light generated by the at least one scintillator.

In the scintillator, light is generated from the electrons by part of their kinetic energy being converted into light in the scintillator material of a scintillator body of the scintillator, such that the kinetic energy of the electrons is lower after the generation of light and their velocity is thus also lower than before.

In accordance with embodiments, the particle beam microscope comprises two scintillators, namely a first scintillator and a second scintillator, wherein the first scintillator comprises a scintillator body fabricated from a first scintillator material, which generates light having a first spectral distribution from electrons, and wherein the second scintillator comprises a scintillator body fabricated from a second scintillator material, which generates light having a second spectral distribution from electrons, the second spectral distribution being different from the first spectral distribution.

The scintillator bodies of the two scintillators can differ with regard to their geometric arrangement relative to the object, such that electrons impinge on the scintillator body of the first scintillator that are emitted by the object in other directions or with other kinetic energies compared to the electrons that impinge on the scintillator body of the second scintillator. Electrons emitted by the object in different directions or with different kinetic energies thus impinge on different scintillator bodies, which in turn generate light having different spectral distributions. The spectral distributions of the generated light, upon subsequent detection by one or more light detectors, can be used to deduce—by way of the detection of the light generated by the different scintillators—the directions or the kinetic energies with which the detected electrons were emitted by the object. Such direction information or information concerning kinetic energies can yield valuable indications of properties of the object, such as, for example, chemical composition and structure in the volume and on the surface of the object.

In this case, beam paths of the light generated by the scintillators can be arranged such that a beam path of the light generated by the first scintillator between the first scintillator and the at least one light detector and a beam path of the light generated by the second scintillator between the second scintillator and the at least one light detector partly overlap one another. This means that an installation space within the particle beam microscope that makes it possible to transfer the light from the scintillators to the at least one light detector serves for transferring the light generated by the first scintillator and for transferring the light generated by the second scintillator. Although the first and second beam paths overlap geometrically in this installation space, it is nevertheless possible—on account of the different spectral distributions of the light respectively generated by the first and second scintillators—for this light, after passing through the installation space in which the two beam paths overlap, to be detected selectively with regard to the wavelengths by the at least one light detector and thus for the scintillator that with higher probability generated the detected light to be deduced for individual detected photons. In contrast to particle beam microscopes in which the beam paths between a plurality of scintillators and the light detectors is assigned thereto are geometrically separated, the present detection of light generated by different scintillators allows a more efficient use of the available installation space and thus possibly an improved integration of the detectors into the particle beam microscope. In accordance with exemplary embodiments, the scintillator bodies of the two scintillators are arranged at a small distance from one another, as measured along a principal axis of the objective lens. In this case, the scintillator body of the first scintillator has at least one region which, as viewed in the direction of the principal axis, does not overlap the scintillator body of the second scintillator, and the scintillator body of the second scintillator has at least one region which, as viewed in the direction of the principal axis, does not overlap the scintillator body of the first scintillator, such that at least one region of the scintillator body of the first scintillator is arranged next to at least one region of the scintillator body of the second scintillator, as viewed in the direction of the principal axis

In addition, a smallest distance between the scintillator body of the first scintillator and the scintillator body of the second scintillator, as measured along a principal axis of the objective lens, can be less than 10 mm, such as less than 5 mm; Furthermore, the scintillator body of the first scintillator can have a surface region which, as viewed in the direction of the principal axis, does not overlap the scintillator body of the second scintillator, such that electrons emitted by the object can impinge both on the scintillator body of the first scintillator and on the scintillator body of the second scintillator.

In accordance with exemplary embodiments, the two scintillator bodies of the first and second scintillator is do not overlap one another, as viewed in the direction of the principal axis, and the scintillator body of the first scintillator is arranged outside a beam path of the light generated by the second scintillator towards the at least one light detector, and the scintillator body of the second scintillator is arranged outside a beam path of the light generated by the first scintillator towards the at least one light detector.

In accordance with embodiments, a first part of the scintillator body of the first scintillator overlaps the scintillator body of the second scintillator, as viewed in the direction of the principal axis, and the first part of the scintillator body of the first scintillator is arranged within a beam path of the light generated by the second scintillator between the second scintillator and the at least one light detector. In this case, the first part of the scintillator body of the first scintillator acts as a light guide for the light generated by the second scintillator. Electrons emitted by the object can impinge on a second part of the scintillator body of the first scintillator that does not overlap the scintillator body of the second scintillator, and the electrons can generate light. This can enable a simplified mounting of the two scintillator bodies by virtue of the fact that the latter do not have to be mounted separately from one another on structures of the particle beam microscope. Rather, the scintillator body of the second scintillator can be mounted on the scintillator body of the first scintillator. In accordance with exemplary embodiments herein, a surface of the scintillator body of the second scintillator is optically coupled to a surface of the scintillator body of the first scintillator.

In accordance with embodiments, the particle beam microscope comprises a light guide arranged in a beam path of the light generated by the first scintillator towards the at least one light detector and in a beam path of the light generated by the second scintillator towards the at least one light detector, wherein the surface of the first scintillator body is optically coupled to a surface of the light guide. Therefore, the light generated in the second part of the scintillator body of the first scintillator can enter the light guide directly, while the light generated in the scintillator body of the second scintillator enters the second part of the scintillator body of the first scintillator, passes through the latter and enters the light guide via the latter.

In accordance with embodiments, the first scintillator body and/or the second scintillator body have/has a shape of an annulus. The annuli can be centred around the principal axis of the objective lens, for example, such that the particle beam generated by the particle source passes through the hole in the annulus in order to reach the object. The scintillator bodies of the two scintillators thus differ with regard to the distance from the principal axis at which the parts of the scintillator bodies on which electrons impinge are arranged. Such an arrangement makes it possible to discriminate electrons with regard to their angle at which they emerge from the object relative to the principal axis, or with regard to their kinetic energy.

In accordance with embodiments, the scintillator bodies of the two scintillators have a shape of annulus segments, such that the parts thereof on which the detected electrons impinge are arranged at the same distance from the principal axis but at different circumferential positions relative to the principal axis. It is thus possible to discriminate electrons emerging from the object with regard to their emission direction in a circumferential direction around the principal axis.

In accordance with embodiments, a particle beam microscope comprises a particle beam source for generating a particle beam, an objective lens for focusing the particle beam in an object plane, a scintillator, a wavelength shifter and at least one light detector. The scintillator is configured to generate light from electrons arriving from the object, wherein the scintillator comprises a scintillator body fabricated from a scintillator material, in which light having a first spectral distribution can be generated from a part of the kinetic energy of incident electrons. The wavelength shifter is configured to convert the light having the first spectral distribution as generated by the first scintillator into light having a second spectral distribution. The at least one light detector is configured to detect the light generated by the scintillator and the light generated by the wavelength shifter.

In this case, too, beam paths of the detected light can be arranged such that a beam path of the light generated by the scintillator between the scintillator and the at least one light detector and a beam path of the light converted by the wavelength shifter between the wavelength shifter and the at least one light detector partly overlap one another. This means that an installation space within the particle beam microscope that makes it possible to transfer the light from the scintillator to the at least one light detector serves both for transferring the light generated by the scintillator and for transferring the light converted by the wavelength shifter. Although the beam paths overlap geometrically in this installation space, it is nevertheless possible—on account of the different spectral distributions respectively of the light generated by the scintillator and of the light converted by the wavelength shifter—for this light, after passing through the installation space in which the two beam paths overlap, to be detected selectively with regard to the wavelengths by the at least one light detector, and thus to deduce, for individual detected photons, whether the detected light originates with higher probability directly from the scintillator or from the wavelength shifter. This design, too, allows an efficient use of the available installation space and thus possibly an improved integration of electron detectors into the particle beam microscope.

In accordance with embodiments, there is a first beam path between a first part of the scintillator body of the scintillator and the at least one light detector, wherein the wavelength shifter is arranged outside the first beam path and no further wavelength shifter is provided in the first beam path, such that the light having the first spectral distribution as generated in the first part of the scintillator body reaches the at least one light detector.

In accordance with embodiments, a surface of the wavelength shifter is optically coupled to a surface of a second part of the scintillator body, set second part being different from the first part, such that the light having the first spectral distribution as generated in the second part of the scintillator body of the scintillator can enter the wavelength shifter and is converted by the latter into light having the second spectral distribution.

In accordance with embodiments, the particle beam microscope furthermore comprises a light guide arranged in a beam path of the light generated by the scintillator towards the at least one light detector and in a beam path of the light generated by the wavelength shifter towards the at least one light detector, wherein a surface of the wavelength shifter is optically coupled to a surface of the light guide. In this case, the wavelength shifter can also be mounted on the light guide, and the scintillator body of the scintillator can be mounted on the wavelength shifter.

As described above, the light having the first spectral distribution and the light having the second spectral distribution different from the first spectral distribution can be generated by a first scintillator and a second scintillator having scintillator bodies composed of different scintillator materials or by a scintillator and a wavelength shifter.

In accordance with embodiments, a centroid of the first spectral distribution is at a first wavelength and a centroid of the second spectral distribution is at a second wavelength, wherein an absolute value of a difference between the first wavelength and the second wavelength is greater than 50 nm. The centroid of the spectral distributions can be calculated in a customary manner by integration over the suitably normalized spectral distributions.

In accordance with embodiments, the first wavelength is less than the second wavelength.

In accordance with embodiments, an optical filter is arrangeable in a beam path of the light having the first spectral distribution and of the light having the second spectral distribution towards the at least one light detector, and allows the light having the first spectral distribution or the light having the second spectral distribution to pass to the at least one light detector better than the light having the respective other spectral distribution. The optical filter can be introduced into the beam path or removed from the latter in order that the light having the first spectral distribution and/or the second spectral distribution is selectively detected successively over time.

In accordance with embodiments, the at least one light detector comprises a first light detector for detecting the light having the first spectral distribution and a second light detector for detecting the light having the second spectral distribution. In this case, a first optical filter is arranged in a beam path of the light having the first spectral distribution towards the first light detector and allows the light having the first spectral distribution to pass to the first light detector better than the light having the second spectral distribution, while a second optical filter is arranged in a beam path of the light having the second spectral distribution towards the second light detector and allows the light having the second spectral distribution to pass to the second light detector better than the light having the first spectral distribution. It is thereby possible for the light having the first spectral distribution and the light having the second spectral distribution to be selectively detected simultaneously.

In accordance with embodiments, the particle beam microscope comprises a dichroic beam splitter, which provides the first optical filter and the second optical filter. By way of example, in this case, the light having the first spectral distribution is substantially reflected at the dichroic beam splitter, while the light having the second spectral distribution substantially passes through the dichroic beam splitter.

The scintillator body of the scintillator and/or the wavelength shifter can each have the shape of an annulus and thus provide advantages for the particle microscope that are similar to those provided by the scintillator bodies of the above-described particle beam microscope comprising the first and second scintillators.

The scintillator body of the scintillator and the wavelength shifter can furthermore have the shape of an annulus segment and thus provide advantages for the particle beam microscope that are the same as those provided by the scintillator bodies of the first and second scintillators of the above-described particle beam microscope.

Embodiments of the disclosure are explained in more detail below with reference to figures.

### BRIEF DESCRIPTION OF THE DRAWINGS

FIG. 1 shows a schematic illustration of a particle beam microscope in accordance with a first embodiment.

FIG. 2 shows a schematic illustration of a particle beam microscope in accordance with a second embodiment.

FIG. 3 is a schematic bottom view of a scintillator arrangement which is usable in the particle beam microscope shown in FIG. 1 or FIG. 2, in accordance with a third embodiment.

FIG. 4 is a schematic sectional view of the scintillator arrangement shown in FIG. 3.

FIG. 5 is a schematic sectional view-corresponding to FIG. 4 with regard to the viewing direction—of another scintillator arrangement which is usable in the particle beam microscope from FIG. 1 or FIG. 2, in accordance with a fourth embodiment.

FIG. 6 is a schematic sectional view-corresponding to FIG. 4—of a scintillator arrangement which is usable in the particle beam microscope from FIG. 1 or FIG. 2, in accordance with a fifth embodiment.

FIG. 7 is a schematic sectional view-corresponding to FIG. 5—of a scintillator arrangement which is usable in the particle beam microscope from FIG. 1 or FIG. 2, in accordance with a sixth embodiment.

FIG. 8 is a schematic view of a light detector arrangement which is usable in the particle beam microscope from FIG. 1 or FIG. 2, in accordance with a seventh embodiment.

FIG. 9 is a schematic view of a light detector arrangement which is usable in the particle beam microscope from FIG. 1 or FIG. 2, in accordance with an eighth embodiment.

FIG. 10 is a plan view of a further scintillator arrangement which is usable in the particle beam microscope shown in FIG. 1 or FIG. 2, in accordance with a ninth embodiment.

### DETAILED DESCRIPTION

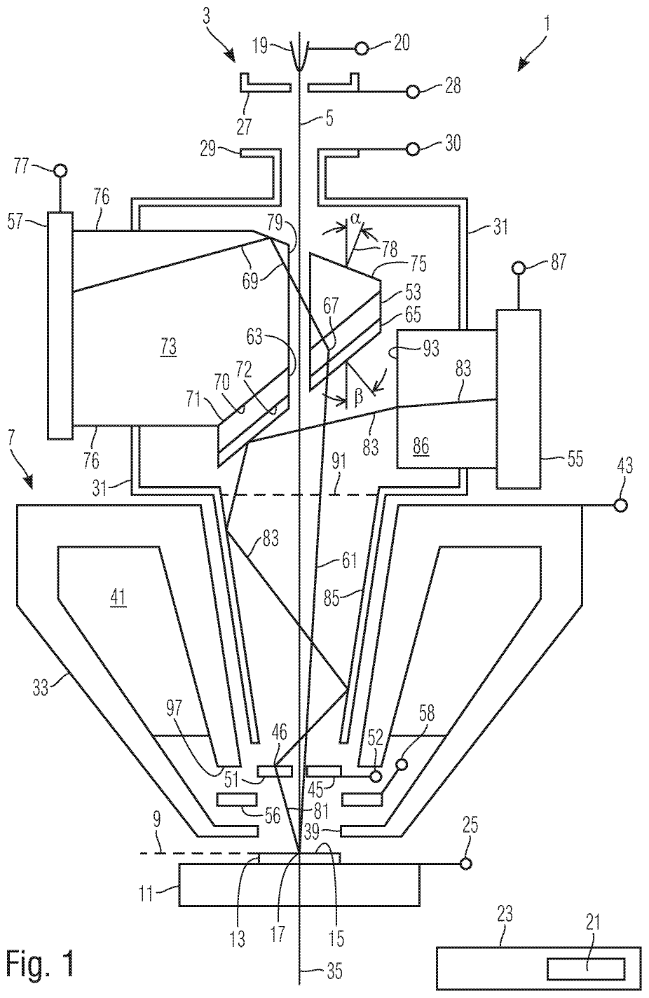

A particle beam microscope 1 shown schematically in FIG. 1 comprises a particle beam source 3 for generating a particle beam 5 and an objective lens 7 for focusing the particle beam 5 in an object plane 9. The particle beam microscope furthermore comprises an object holder 11, which holds an object 13 to be examined such that the surface 15 of the object is arranged in the object plane 9. The particle beam 5 impinging on the object 13 generates electrons at a location 17 at which the particle beam 5 impinges on the surface 15 of the object 13, which electrons emerge from the object 13 and are detected by the particle beam microscope 1, as will be described below.

The particle beam 5 generated by the particle beam source 3 is an electron beam, the particle beam source 3 having a cathode 19 for the purpose of generating the electron beam. A potential supply system 21, which is part of a controller 23 of the particle beam microscope 1, feeds an adjustable electrical potential to the cathode 19 via a terminal 20. The potential supply system 21 likewise feeds an adjustable electrical potential to the object holder 11 via a terminal 25. The electrical potential for the object holder 11 can be the earth potential, for example. The difference between the potential of the object holder 11 and the potential of the cathode 19 determines the kinetic energy with which the electrons of the electron beam 5 are incident on the surface 15 of the object 31.

The particle beam source 3 furthermore comprises an extractor 27, to which the potential supply system 21 feeds, via a terminal 28, an electrical potential selected such that electrons are extracted from the cathode 19. The cathode 19 can also be heated by a heating system, not illustrated in FIG. 1. The electrons extracted from the cathode 19 pass through a hole in the extractor 27 and form the particle beam 5. The electrons are accelerated towards an anode 29, to which the potential supply system 21 feeds a corresponding anode potential via a terminal 30. The anode 29 forms an upper end-near the particle beam source 3—of a beam tube 31, through which the particle beam 5 passes. A lower end of the beam tube 31 is arranged near the object plane 9, such that the electrons of the particle beam 5 with the kinetic energy with which they enter the beam tube 31 in an accelerated manner through the anode 29 pass close up to the object 13. Between the lower end of the beam tube 31, which is at the potential of the anode 29, and the object 13, which is at the potential of the object holder 11, the electrons are retarded, such that they are incident on the surface of the object 13 with the kinetic energy determined by the potential difference between the cathode 19 and the object holder 11.

Prior to incidence on the object 13, the particle beam 5 is focused by the objective lens 7. Between the particle beam source 13 and the objective lens 7, further particle-optical devices, not illustrated in the figure, such as a condenser lens, and aperture stop and a stigmator, for example, can be provided in order to influence and shape the particle beam 5, such that the spot illuminated by the particle beam 5 on the surface 15 of the object 13 is as small as possible. A finely focused particle beam 5 that illuminates a small beam spot enables a high spatial resolution of the particle beam microscope 1.

The objective lens 7 provides a magnetic field for focusing the particle beam 5. For this purpose, the objective lens 7 comprises a magnetic yoke 33 arranged rotationally symmetrically around a principal axis 35 of the objective lens 7. In the example explained here, the principal axis 35 of the objective lens 7 coincides with a principal axis of the particle beam microscope 1, relative to which other components such as the particle beam source 19, for example, are centred. The beam path of the particle beam 5 extends substantially along the principal axis 35 and thus passes through the objective lens 7 along the principal axis 35. The magnetic yoke 33 comprises an upper pole end 37 and a lower pole end 39 and surrounds a magnetic coil 41, to which an electrical excitation current is fed by the controller 23. The current generates a magnetic field that travels substantially in the magnetic yoke 33 and emerges from the magnetic yoke 33 at the pole ends 37, 39 and acts on the particle beam 5 in such a way that the latter is focused.

The lower pole end 39 is arranged near the object plane 9 and has a central hole, through which the particle beam 5 passes. The lower pole end 39 is also at an adjustable electrical potential fed to the magnetic yoke 33 via a terminal 43 by the potential supply system 21. The potential of the lower pole end 39 can be equal to or different from the potential of the object holder 11. However, the electrons of the particle beam 5 are retarded, as described above, on their path between the lower end of the beam tube 31 and the surface 15 of the object 13. This retardation is brought about by an electric field determined inter alia by the potential difference between the beam tube 31 and the lower pole end 39 or the object holder 11. This electric retardation field likewise has a focusing effect on the particle beam 5, such that the latter is focused by the joint effects of the magnetic field and this electrostatic field.

Furthermore, electrostatic or magnetic beam deflectors, not illustrated in FIG. 1, are provided in the region of the objective lens 7, and are excited by the controller 23 in order to deflect the particle beam 5, such that the incidence location 17 of the particle beam 5 on the surface 15 of the object 13 can be varied in a targeted manner. For example, by way of the control of the beam deflectors, the controller 23 can scan the incidence location 17 over a specific region of the surface 15 of the object 13, wherein the particles to be detected arise during the scanning at the respective incidence locations 17 on account of the interaction of the particles of the particle beam 5 with the object 13. These particles to be detected comprise electrons that emerge from the object 13 with different kinetic energies. In accordance with a conventional classification, a distinction is made between secondary electrons and backscattered electrons. The secondary electrons, upon emerging from the surface 15 of the object 13, have kinetic energies of a few electronvolts, for example up to 50 eV, while the backscattered electrons typically have a significantly higher kinetic energy that may be equal to the kinetic energy with which the electrons of the particle beam 5 are incident on the object 13. Both kinds of electrons are intended to be able to be detected effectively by the particle beam microscope 1.

For this purpose, the particle beam microscope 1 comprises a first scintillator arrangement 51 and a second scintillator arrangement 53, and also a first light detector arrangement 55 and a second light detector arrangement 57. The first and second scintillator arrangements 51, 53 and the first and second light detector arrangements 55, 57 are described in greater detail below with reference to FIGS. 1 to 10.

The first scintillator arrangement 51 can have a shape approximated to a shape of a plate, with a main surface 45 facing the object plane 9 and a main surface 46 facing the particle beam source 3. It can have a circular outer circumference or a differently shaped outer circumference, and a hole which is centred relative to the principal axis 35 and through which the particle beam 5 passes. In the embodiment shown in FIG. 1, as viewed along the beam path of the particle beam 5, the first scintillator arrangement 51 is arranged between that end of the beam tube 31 which is near the object plane 9 and the object plane 9. For example, the lower pole end 39 of the objective lens 7 is also arranged between the first scintillator arrangement 51 and the object plane 9. The first scintillator arrangement 51 has a terminal 52, via which the first scintillator arrangement 51 and thus the surfaces 45 and 46 thereof can be brought to an adjustable potential relative to the potentials of the beam tube 31, the object holder 11 and the lower pole end 39 by the potential supply system 21. In the exemplary embodiment of the particle beam microscope 1 shown in FIG. 1, as viewed along the beam path of the particle beam 5, a ring electrode 56 with an opening centred with respect to the principal axis 35 is also provided between the first scintillator arrangement 51 and the object plane 9. The potential supply system 21 likewise feeds an adjustable electrical potential to the ring electrode 56 via a terminal 58. The electrical potentials of the beam tube 31, the first scintillator arrangement 51, the ring electrode 56, the lower pole end 39 and the object holder 11 influence firstly the electrons of the particle beam 5 on their path towards the object 13 but also the secondary electrons and backscattered electrons that emerge from the object 13 at the incidence location 17 of the particle beam 5 on the object. For example, these electric fields accelerate the secondary electrons which emerge from the object 13 and which initially have a relatively low kinetic energy, in such a way that they are guided away from the object 13 and accelerated to an extent such that their kinetic energy is high enough to penetrate into scintillator materials of the first scintillator arrangement 51 and the second scintillator arrangement 53 and to generate light there which is detectable by the light detector arrangements 55 and 57.

If the electrical potential fed to the object holder 11 via the terminal 25 is designated by V1, the potential fed to the first scintillator arrangement 51 via the terminal 52 is designated by V2 and the electrical potential fed to the beam tube 31 via the terminal 30 is designated by V3, the electrical potentials V1, V2 and V3 can advantageously be chosen such that they satisfy the following relations: V2>V1, V3>V1 and V2>V3. Moreover, if the electrical potential fed to the ring electrode 56 via the terminal 58 is designated by V4, then it can furthermore advantageously be chosen such that the relations V4>V1 and V4>V2 are satisfied.

Electrons which emerge from the object 13 with comparatively low kinetic energy, i.e. primarily the so-called secondary electrons, are accelerated in the above-described electrostatic fields above the object 13 away from the object 13 towards the particle beam source 3, pass through the central opening in the first scintillator arrangement 51 and enter the beam tube 31 via the lower end thereof. With the reference sign 61, one such electron is represented by its trajectory by way of example and in a simplified manner. In actual fact, the shape of the trajectory deviates from a straight line since the electrostatic and magnetic fields of the objective lens 7 also act on the electrons in transverse directions with respect to the principal axis 35. This electron 61 departs from the principal axis 35 to such an extent that it impinges on the second scintillator arrangement 53 and generates light therein.

The second scintillator arrangement 53 has a drilled hole 63 centred with respect to the principal axis 35, the beam path of the particle beam 5 extending through the hole. Before penetrating into the second scintillator arrangement 53, the electron 61 passes through a mirror layer 65, which is described below. The electron 61 generates light at an interaction location 67 within the second scintillator arrangement 53. With the reference sign 69, such light is represented by a trajectory by way of example in FIG. 1.

This light 69 emerges from the second scintillator arrangement 53 at an opposite main surface 71 thereof in relation to the mirror layer 65 and enters a light guide 73. A first surface region 70 of the light guide 73 is in surface contact with the second scintillator arrangement 53 at the main surface 71 thereof or is at a small distance therefrom, such that the light guide 73 is optically coupled to the second scintillator arrangement 53 and a high proportion of the light generated in the second scintillator arrangement 53 crosses into the light guide 73. The light guide 73 has a second surface region 75 and further surface regions 76, at which the light is internally reflected and can pass to the second light detector arrangement 57 in order to to be detected by the latter.

The second light detector arrangement 57 generates electrical signals representing the detected light, and outputs the detection signals via one or more terminals 77 to the controller 23 of the particle beam microscope 1.

The second surface region 75 of the light guide 73 is situated opposite the first surface region 70 of the light guide 73 and has a surface normal 78 that is at an angle α with respect to the beam direction of the particle beam 5. The angle α can be in a range of 0° to 70°, for example. For example, the angle α can be less than 45°. The light guide 73 also has a drilled hole 79, which is aligned with the drilled hole 63 of the scintillator 53 and through which the beam path of the particle beam 5 extends.

With the reference sign 81, an electron that emerges from the object 13 with higher kinetic energy, for example a so-called backscattered electron, is represented by its trajectory by way of example in FIG. 1. On account of its higher kinetic energy, the electron 81 can depart further from the principal axis 35 of the particle beam microscope 1 than the electron with lower energy which is designated by the reference sign 61 by way of example and which moves with just a low velocity component transversely with respect to the principal axis 35 and therefore passes through the central hole in the first scintillator arrangement 51. The electron 81 departs further from the principal axis 35 than would correspond to the radius of the central hole in the first scintillator arrangement 51 and impinges on the first scintillator arrangement 51 and generates light therein.

The electron 81 generates light at an interaction location within the first scintillator arrangement 51. An exemplary trajectory of a light beam that arises in the process is designated by the reference sign 83 in FIG. 1. The light beam 83 impinges on an inner wall 85 of the beam tube 31 and is reflected twice at this inner wall 85 before it impinges on the surface of the mirror 65, at which there occurs a renewed reflection towards a light guide 86, into which the light beam 83 penetrates and is guided towards the first light detector arrangement 55. The first light detector arrangement 55 detects the light beam 83 and converts it into an electrical signal, which is output to the controller 23 of the particle beam microscope 1 via one or more terminals 87 of the first light detector arrangement 55.

The two reflections of the light beam 83 at the inner wall 85 of the beam to 31 are by way of example. The number of reflections can be greater than two, and the light generated by the first scintillator arrangement 51 can also impinge directly on the mirror 65 or pass to the mirror 65 after only one reflection at the inner wall 85 of the beam tube 31. In order to improve the reflection properties of the inner wall 85 of the beam tube 31, the inner wall is processed so as to be a mirror surface. This processing can comprise polishing of the inner wall 85. For example, the processing can be effected such that an average surface roughness Ra of the inner wall is less than 0.4 μm.

As is evident from FIG. 1, the inner wall 85 of the beam tube 31 in the region viewed along the beam path of the particle beam 5 between the second scintillator arrangement 53 or the mirror 65 and the first scintillator arrangement 51 is embodied as a surface having a conical shape. For example, the beam tube 31 at its end near the object plane 9 or the first scintillator arrangement 51 has a cross-sectional area measured perpendicularly to the principal axis 35 which is more than two times smaller than the cross-sectional area of the beam tube in a cross-sectional plane 91 near the second scintillator arrangement 53. For example, the cross-sectional area of the beam tube 31 increases continuously from its end near the object plane 9 towards the plane 91.

The conical shaping of the inner wall 85 of the beam tube 31 has the effect that light beams which emerge from the first scintillator arrangement 51 in a transverse direction with respect to the principal axis 35 are aligned in the direction of the principal axis 35 to a greater degree with each reflection at the conical inner wall 85 and then, after the reflection at the surface of the mirror 65, impinge almost perpendicularly on a surface 93 of the light guide 86. A smaller portion of the light impinging almost perpendicularly on the surface 93 of the light guide 86 is reflected at the surface 93 compared with light that impinges on the surface 93 at a greater angle with respect to the perpendicular to the surface. The conical shape of the inner wall 85 of the beam tube 31 thus has the effect that the proportion of the light generated by the first scintillator arrangement 51 which penetrates into the light guide 86 is increased, thereby also increasing the probability of detection of electrons by the first scintillator arrangement 51.

The surface of the mirror 65 is oriented relative to the principal axis 35 such that a surface normal of the mirror 65 forms an angle β with the principal axis 35, the angle being 40° in the example in FIG. 1. In general, the angle β can be in a range of between 25° and 65° or 30° and 60°. In the example illustrated in FIG. 1, a surface normal to the surface 93 of the light guide 86 is oriented at an angle of 90° with respect to the principal axis 35.

In the example shown in FIG. 1, the first surface region 70 of the light guide 73 is parallel to the surface of the mirror 65, such that the first surface region 70 of the light guide 73 is also oriented at the angle β with respect to the principal axis 35. Furthermore, the first surface region 70 is not far away from the second surface region 75 of the light guide 73, such that the two surface regions 70 and 75 delimit a part of the light guide 73 which has a conical shape. A smallest distance between the first surface region 70 and the second surface region 75 is smaller than 5 mm or smaller than 3 mm, for example. An opening angle γ can be defined as an angle between a surface normal of the first surface region 70 and the surface normal of the second surface region 75. The opening angle γ is for example in a range of between 15° and 55°, such as in a range of between 20° and 50°.

In the case of the particle beam microscope 1, principally secondary electrons pass through the central opening of the first scintillator arrangement 51 to the second scintillator arrangement 53 in order to generate light therein, which is finally detected by the light detector arrangement 57. Substantially backscattered electrons pass to the first scintillator arrangement 51 and generate light therein, which is possibly reflected after one or more reflections at the inner wall 85 of the beam tube 31 via the mirror 65 towards the light detector arrangement 55 in order to be detected by the latter. In this case, the first scintillator arrangement 51 is arranged relatively near the object plane 9, such that backscattered electrons that emerge from the surface 15 of the object 13 at the location 17 at a relatively large solid angle impinge on the first scintillator arrangement 51. The particle beam microscope 1 thus has a comparatively high detection probability for backscattered electrons emerging from the object 13.

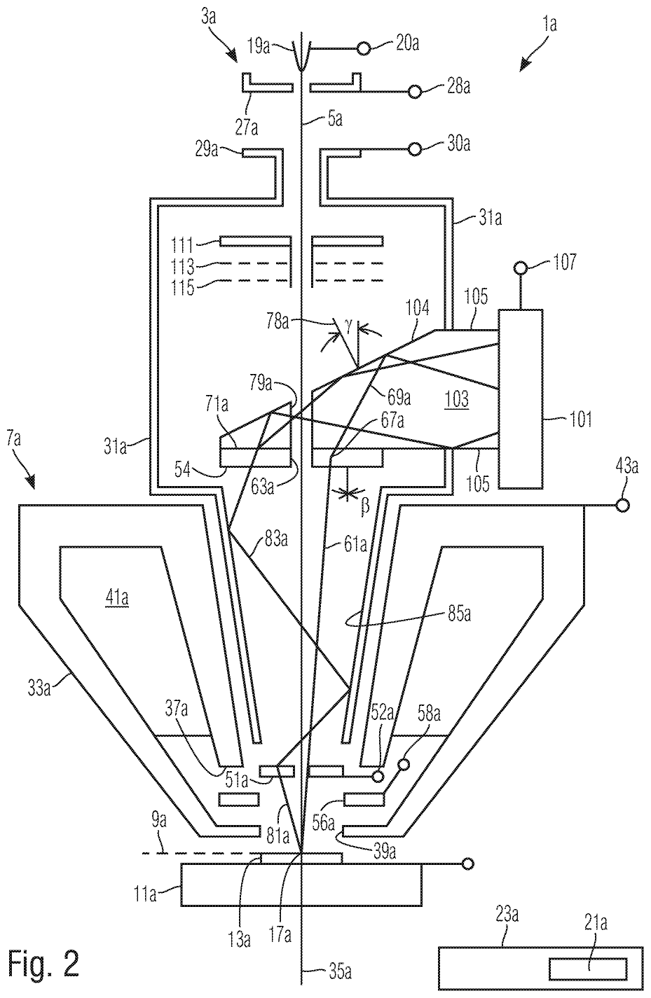

A further embodiment is explained below with reference to FIG. 2. In this case, components which are similar to components of the embodiment explained with reference to FIG. 1 in regard to their structure and/or function are designated by the same reference sign, but provided with an additional letter for differentiation purposes. For an understanding of the individual components whose description is not repeated or is only partly repeated, reference should be made to the description of the preceding embodiments and the introduction to the description.

A particle beam microscope 1a shown in FIG. 2 has a similar set-up to the particle beam microscope explained with reference to FIG. 1 by virtue of the fact that it comprises a particle beam source 3a and an objective lens 7a in order to focus a particle beam 5a generated by the particle beam source 3a in an object plane 9a. The particle beam source 3a likewise comprises a cathode 19a and an extractor 27a. The particle beam 5a likewise passes through a beam tube 31a, the lower end of which is arranged within the objective lens 7a. The objective lens 7a generates a magnetic field that focuses the particle beam 5a with the aid of a coil 41a, which is partly enclosed by a magnetic yoke 33a having an upper pole end 37a and a lower pole end 39a.

A first scintillator arrangement 51a is arranged between the lower end of the beam tube 31a and the object plane 9a. A ring electrode 56a can likewise be arranged between the first scintillator arrangement 51a and the object plane 9a. Besides the first scintillator arrangement 51a arranged near the object plane 9a, the particle beam microscope 1a comprises a second scintillator arrangement 53a, which is arranged at a greater distance from the object plane 9a. The first scintillator arrangement 51a serves principally to generate light from backscattered electrons 81a, while the second scintillator arrangement 53a principally serves to generate light from secondary electrons that have passed through a central opening of the first scintillator arrangement 51a.

The embodiment shown in FIG. 2 differs from that in FIG. 1 substantially by virtue of the fact that a common light detector arrangement 101 is provided for the detection of the light generated by the first scintillator arrangement 51a and for the detection of the light generated by the second scintillator arrangement 53a.

An electron which emanates from an incidence location 17a of the particle beam 5a at the surface of an object 13a and which is represented by a trajectory 61a by way of example and in a simplified manner in FIG. 2 penetrates into the second scintillator arrangement 53a and generates light at an interaction location 67a. An exemplary light beam generated from the electron 61a is designated by the reference sign 69a in FIG. 2. This light beam emerges from the second scintillator arrangement 53a at the surface 71a thereof facing away from the object plane 9a and enters a light guide 103, which is optically coupled to the second scintillator arrangement 53a. The light beam 69a is reflected one or more times at inner surfaces of the light guide 103 before it reaches the light detector arrangement 101, which detects the light and outputs a detection signal corresponding to the light to a controller 23a of the particle beam microscope 1a via one or more terminals 107.

Besides the secondary electrons 61a impinging on the second scintillator arrangement 53a, light beams 83a generated by electrons in the first scintillator arrangement 51a also pass through the space within the beam tube 31a and between the first scintillator arrangement 51a and the second scintillator arrangement 53a. These light beams 83a are reflected if appropriate one or more times at an inner wall 85a of the beam tube 31a before they impinge on the second scintillator arrangement 53a. However, unlike the second scintillator arrangement 53 in the embodiment in FIG. 1, the second scintillator arrangement 53a does not bear a mirror surface, and so the light 83a generated by the first scintillator arrangement 51a can pass through the second scintillator arrangement 53a and enter the light guide 103. The light guide 103 has a surface region 104 situated opposite the second scintillator arrangement 53a, and also further surface regions 105. In the light guide 103, the light 83a is reflected one or more times at the surface regions 104, 105 of the light guide in order then to be detected by the light detector arrangement 101.

A main surface 54 of the second scintillator arrangement 53a is oriented orthogonally to the direction of a principal axis 35a of the objective lens 7a. Consequently, an angle β between a surface normal to the surface 54 and the direction of the principal axis 35a is 0° in the example in FIG. 2, while the corresponding angle β in the embodiment in FIG. 1 was 40°. Other possibilities for the selection of the angle β in the embodiment in FIG. 2 are such that the angle β is greater than 0° but less than 20°, such as less than 10°. The light guide 103 also has a drilled hole 79a aligned with a drilled hole 63a in the second scintillator arrangement 53a in order to to allow the beam path of the particle beam 5a to pass through the light guide 103 and the second scintillator arrangement 53a.

The surface region 104 of the light guide 103 also has a function as a mirror surface for the light 83a which has been generated by the first scintillator arrangement 51a and has passed through the second scintillator arrangement 53a, in order to reflect this light towards the light detector arrangement 101. The surface region 104 has a surface normal 78a that is at an angle α with respect to the beam direction of the particle beam 5a. The angle α can be for example in a range of between 15° and 55°, such as in a range of between 20° and 50°, for example less than 45°. As in the exemplary embodiment shown in FIG. 1, in the exemplary embodiment in FIG. 2 as well, the light guide 103 forms a wedge whose opening angle γ can be defined as the angle between the surface normal 78a of the surface region 104 of the light guide 103 and the surface normal of that surface region of the light guide 103 which is coupled to the second scintillator 53a. The opening angle γ is for example in a range of between 15° und 55°, such as in a range of between 20° and 50°.

In the light guide 103, the beam path of the light generated by the first scintillator arrangement 51a towards the light detector arrangement 101 and the beam path of the light generated by the second scintillator arrangement 53a towards the light detector arrangement 101 overlap. In a simplified embodiment, the light detector arrangement 101 can detect the light generated by the scintillator arrangement 51a and the light generated by the scintillator arrangement 53a, without discriminating between the two kinds of light. Advantageously, however, the first light detector arrangement 101 is configured such that the detection can discriminate between the light generated by the scintillator arrangement 51a and the light generated by the scintillator arrangement 53a. This is possible for example if the spectral distributions of the light generated by the scintillator arrangement 51a and the light generated by the scintillator arrangement 53a differ from one another. This can be achieved for example by the use of scintillator bodies composed of different scintillator materials, which generate light having different spectral distributions from electrons, in the scintillator arrangement of 51a and the scintillator arrangement 53a. Examples of light detector arrangements which are suitable as the light detector arrangement 101 in this regard are explained below.

Besides the scintillator arrangements 51a and 53a, the particle beam microscope 1a also comprises a further detection system for electrons emerging from the object 13a. This detection system comprises an electron detector 111 and a first grid 113 and a second grid 115, which are arranged in the beam path of the electrons emitted by the object 13a between the object plane 9a and the detector 111. Electrons that have passed through the opening in the first scintillator arrangement 51a and the drilled holes 63a and 79a in the second scintillator arrangement 53a and the light guide 103, respectively, can impinge on the electron detector 111 in order to be detected by the latter. A potential supply system 21a applies adjustable potentials to the grids 115 and 113. These potentials can be varied in order to select the energy of the electrons that reach the detector 111. In this case, a minimum kinetic energy of the electrons that can be detected by the detector 111 is adjusted by way of a potential difference between the object and the grid 113. By changing the potential at the grid 113, it is possible to select the kinetic energy of the electrons that reach the grid 113 and pass through the latter in order subsequently to be detected by the detector 111.

A description is given below of embodiments of scintillator arrangements which can be used as the first and/or the second scintillator arrangement of the particle beam microscopes described with reference to FIGS. 1 and 2. Furthermore, the scintillator arrangements described can also be used in other particle beam microscopes which have a different set-up and provide different functions compared to the particle beam microscopes explained with reference to FIGS. 1 and 2.

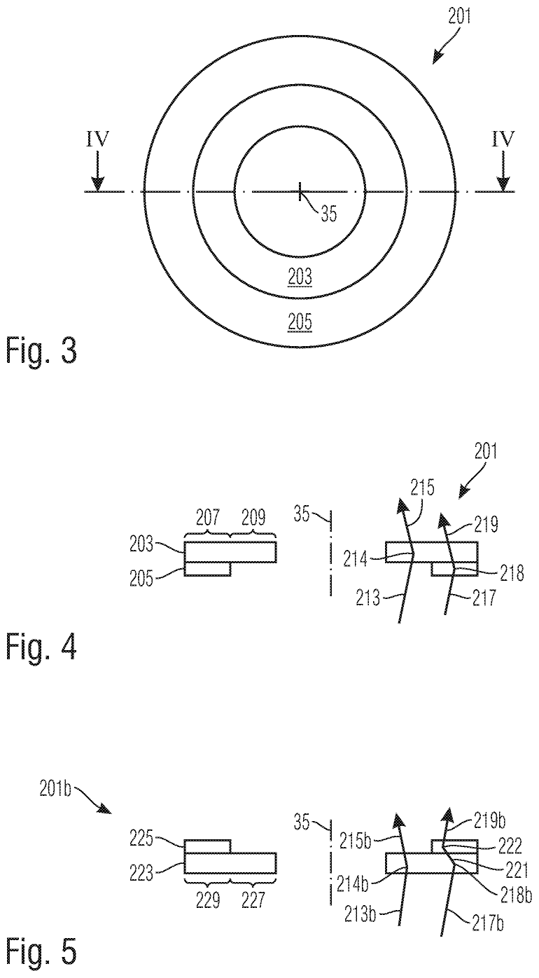

FIG. 3 is a schematic illustration of a bottom view of a scintillator arrangement 201 which can be used for example as the first scintillator arrangement 51 in the particle beam microscope in FIG. 1 and as the first scintillator arrangement 51a in the particle beam microscope in FIG. 2. It is a view from below of the main surface 45 of the first scintillator arrangement 51 from FIG. 1. FIG. 4 is a schematic sectional view of the scintillator arrangement 201 shown in FIG. 3 along a line IV-IV in FIG. 3.

The scintillator arrangement 201 comprises two scintillators configured to generate light from electrons arriving from the object. The first scintillator has a scintillator body 203, and the second scintillator has a scintillator body 205. The two scintillator bodies 203, 205 each have the shape of an annulus that can be centred relative to the principal axis 35 of the objective lens 7 in the bottom view in FIG. 3, and the shape of a flat plate in the sectional view in FIG. 4. The two scintillator bodies 203, 205 are arranged at a small distance from one another, for example at less than 5 mm from one another. In the embodiment illustrated in FIGS. 3 and 4, the scintillator bodies 203, 205 bear against one another with their surfaces. The scintillator body 203 has a first region 207, which overlaps the scintillator body 205 as viewed in the direction of the principal axis 35. The scintillator body 203 furthermore has a second region 209, which does not overlap the scintillator body 205 as viewed in the direction of the principal axis 35. Accordingly, as measured in the direction of the principal axis 35, the two scintillator bodies 203, 205 are arranged with a small distance or with no distance between one another, but each of the scintillator bodies has at least one region arranged alongside at least one region of the other scintillator body as viewed in the direction of the principal axis 35 or in the bottom view in FIG. 3.

The scintillator bodies 203, 205 are fabricated from mutually different scintillator materials, such that the scintillator body 205 generates light having a spectral distribution which is different from a spectral distribution of the light generated by the scintillator body 203. The spectral distributions of the light generated by the scintillator bodies 203, 205 each have a centroid at a specific wavelength, where the wavelengths of the centroids differ from one another by more than 50 nm, for example. Examples of suitable scintillator material for the scintillator bodies 203, 205 are monocrystalline YAP scintillator material or pulverulent P47 scintillator material. By way of example, the scintillator body 203 can be formed from monocrystalline YAP scintillator material, while the scintillator body 205, as a powder layer of P47 scintillator material, is applied to the underside of the scintillator body 203 in the first region 207 thereof.

A line 213 in FIG. 4 represents a trajectory of an electron arriving from the object, which impinges on the second region 209 of the scintillator body 203 and penetrates into the latter. Light is generated from the electron at an interaction location 214 in the scintillator body 203, and leaves the scintillator body, an exemplary trajectory for the light being represented by an arrow 215 in FIG. 4.

A line 217 in FIG. 4 represents a trajectory of an electron arriving from the object, which impinges on the scintillator body 205 and penetrates into the latter. Light is generated from the electron at an interaction location 218 in the scintillator body 205, an exemplary trajectory for the light being represented by an arrow 219 in FIG. 4. The light emerges from the scintillator body 205 and enters the scintillator body 203, which is optically coupled to the scintillator body 205. This scintillator body 203 acts as a light guide for the light 219, such that the light 219 passes through the scintillator body 203 and emerges therefrom upwards in FIG. 4.

In order to prevent emission of light by the scintillator body 203 as a result of absorption of light 219 in the scintillator body 203, the wavelength of the centroid of the spectral distribution of the light generated in the scintillator body 205 can be longer than the wavelength of the centroid of the spectral distribution of light generated in the scintillator body 203. In addition, an optical filter between the scintillator bodies 205 and 203 in the beam path of the light 219 can trim the spectral distribution emitted by the scintillator body 205 in a spectral range in which it overlaps the spectral distribution emitted by the scintillator body 203.

Consequently, from the electrons arriving from the object, the scintillator arrangement 201 generates light having two different spectral distributions, specifically depending on which of the two scintillator bodies 203, 205 the respective electron arriving from the object impinges on. The regions of the scintillator bodies 203 and 205 on which the electrons arriving from the object can impinge are arranged at geometrically different positions relative to the object. In this case, the positions of the two scintillator bodies differ little as viewed in the direction of the principal axis 35 of the objective lens 7, while they differ significantly in the transverse direction with respect thereto. The light 215, 219 generated by the two scintillators can subsequently be detected by a suitable light detector. On the way towards the light detector, the beam paths of the light 215 generated by the scintillator body 203 and of the light 219 generated by the scintillator body 205 overlap one another. The beam paths of the two kinds of light overlap in the sense that along the two beam paths, for example, there are locations through which light beams of the light generated by the scintillator body 203 and also light beams of the light generated by the scintillator body 205 pass. The light detector can be configured to detect selectively with regard to the wavelength of the light 215, 219, such that the detection signal of the light detector contains information in regard to the incidence location of the electron 213, 270 generating the light 215, 219.

The scintillator arrangement 201 can be used in any suitable particle beam microscope. By way of example, the scintillator arrangement 201 can be used as the first scintillator arrangement 51 in the particle beam microscope 1 in FIG. 1. For this purpose, the two scintillator bodies 203 and 205 can be secured for example to the lower end of the beam tube 31, to the upper pole end 37 of the magnetic yoke 33, the lower pole end 39 of the magnetic yoke 33, the ring electrode 56 or to some other component of the particle beam microscope 1. As shown by the exemplary light beam 83 in FIG. 1, the light beams of the light generated by the scintillator bodies 203 and 205 can pass to the first light detector arrangement 55 in order to be detected by the latter. The beam path of the light generated by the scintillator body 203 and the beam path of the light generated by the scintillator body 205 overlap between the scintillator arrangement 51 and the first light detector arrangement 55. The first light detector arrangement 55 can detect the light generated by the scintillator body 203 and the light generated by the scintillator body 205, without discriminating between the two kinds of light. Advantageously, the first light detector arrangement 55 is configured such that the detection can discriminate between the light generated by the scintillator but in 203 and the light generated by the scintillator body 205. This is possible since the spectral distributions of the light generated by the scintillator body 203 and the light generated by the scintillator body 205 differ from one another. Examples of light detector arrangements which are suitable as the first light detector arrangement 55 in this regard are explained below.

By way of example, the scintillator arrangement 201 can also be used as the second scintillator arrangement 53 in the particle beam microscope 1 in FIG. 1. This is possible both for the particle beam microscope 1 with the first scintillator arrangement 51 and for embodiments without the first scintillator arrangement 51. For this purpose, the two scintillator bodies 203 and 205 can be secured to the light guide 73, for example, and the mirror layer 65 can cover the areas of the scintillator bodies 203 and 205 that are visible in the bottom view in FIG. 3. As shown by the exemplary light beam 69 in FIG. 1, the light beams of the light generated by the scintillator bodies 203 and 205 can then pass to the second light detector arrangement 57 in order to be detected by the latter. The beam path of the light generated by the scintillator body 203 and the beam path of the light generated by the scintillator body 205, in the light guide 73, overlap between the second scintillator arrangement 53 and the second light detector arrangement 57. The second light detector arrangement 57 can also detect the light generated by the scintillator body 203 and the light generated by the scintillator body 205, without discriminating between the two kinds of light. Advantageously, the second light detector arrangement 57 is configured such that the detection can discriminate between the light generated by the scintillator body 203 and the light generated by the scintillator body 205.

The scintillator bodies 203 and 205 of the two scintillators each have the shape of an annulus in the example shown here. However, it is also possible for one, the other or both of the scintillators to have a plurality of scintillator bodies in each case. By way of example, a scintillator can comprise a plurality of scintillator bodies arranged in a manner distributed around the principal axis. Furthermore, the scintillators can comprise for example electrically conductive layers provided on surfaces of the scintillator bodies in order to avoid local electrostatic charges at the surfaces of the scintillator bodies. The electrically conductive layers can be light-reflecting by virtue of their consisting of a thin metal layer, for example, or they can be light-transmissive by virtue of their being fabricated from indium tin oxide, for example.

FIG. 5 is a cross-sectional illustration—corresponding to FIG. 4 with regard to the viewing direction—of a scintillator arrangement 201b in accordance with a further embodiment. The scintillator arrangement 201b comprises a scintillator body 223 having the shape of an annulus and a wavelength shifter 225 likewise having the shape of an annulus. The scintillator body 223 has a first region 227, which does not overlap the wavelength shifter 225 as viewed in the direction of the principal axis 35, and furthermore a second region 229, which overlaps the wavelength shifter 225 as viewed in the direction of the principal axis 35. The wavelength shifter 225 is optically coupled to the scintillator body 223 and in this case is arranged at a slight distance therefrom or bears directly against this.

By way of example, one of the scintillator materials described above can be used as scintillator material for the scintillator body 223. The scintillator body 223 generates light having a first spectral distribution from electrons. The wavelength shifter 225 converts light having the first spectral distribution into light having a second spectral distribution by virtue of the fact that it absorbs the light having the first spectral distribution and re-emits it with the second spectral distribution. In this case, a wavelength of the centroid of the second spectral distribution is greater than the wavelength of the centroid of the first spectral distribution. Examples of suitable scintillator materials for forming the wavelength shifter are:
POPOP (1,4-bis-[2-(5-phenyloxazolyl)]-benzene; C₂₄H₁₆N₂O₂)
bis-MSB (1,4-bis(2-methylstyryl)-benzene; C₂₄H₂₂)
BBQ (benzimidazo-benzisoquinolin-7-one)

A line 213b in FIG. 5 represents a trajectory of an electron arriving from the object, which impinges on the first region 227 of the scintillator body 223 and penetrates into the latter. Light having the first spectral distribution is generated from the electron at an interaction location 214b in the scintillator body 223, and leaves the scintillator body 223, an exemplary trajectory for the light being represented by an arrow 215b in FIG. 5.

A line 217b in FIG. 5 represents a trajectory of an electron arriving from the object, which impinges on the second region 229 of the scintillator body 223 and penetrates into the latter. Light having the first spectral distribution is generated from the electron at an interaction location 218b in the scintillator body 223, an exemplary trajectory for the light being represented by a line 221 in FIG. 5. The light 221 having the first spectral distribution leaves the scintillator 223 and enters the wavelength shifter 225 optically coupled to the scintillator 223. At an interaction location 222 in the wavelength shifter 225, the light having the first spectral distribution is converted into light having the second spectral distribution, which light leaves the scintillator body 225, an exemplary trajectory for the light being represented by an arrow 219b in FIG. 5.

The scintillator arrangement 201b can be used in any suitable particle beam microscope. By way of example, the scintillator arrangement 201b can be used as the first scintillator arrangement 51 in the particle beam microscope 1 in FIG. 1. For this purpose, the scintillator body 223 and the wavelength shifter 225 can be secured for example to the lower end of the beam tube 31, to the upper pole end 37 of the magnetic yoke 33, the lower pole end 39 of the magnetic yoke 33, the ring electrode 56 or to some other component of the particle beam microscope 1. As shown by the exemplary light beam 83 in FIG. 1, the light beams of the light generated by the scintillator body 223 and the wavelength shifter 225 can pass to the first light detector arrangement 55 in order to be detected by the latter. The beam path of the light generated by the scintillator body 223 and the beam path of the light generated by the wavelength shifter 225 overlap between the scintillator arrangement 51 and the first light detector arrangement 55. The first light detector arrangement 55 can detect the light generated by the scintillator body 223 and the light generated by the wavelength shifter 225, without discriminating between the two kinds of light. Advantageously, the first light detector arrangement 55 is configured such that the detection can discriminate between the light generated by the scintillator body 223 and the light generated by the wavelength shifter 225. This is possible since the spectral distributions of the light generated by the scintillator body 223 and the light generated by the wavelength shifter 225 differ from one another.

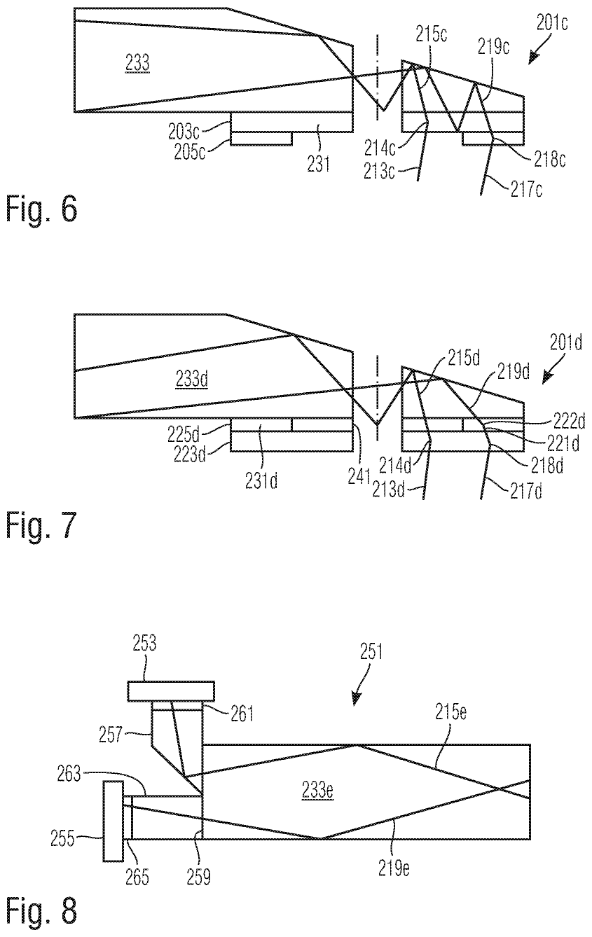

FIG. 6 is a schematic sectional view of an arrangement consisting of a light guide 233 and a scintillator arrangement 201c, corresponding to FIG. 4, which can be used for example as the second scintillator arrangement 53 in the particle beam microscope in FIG. 1 and as the second scintillator arrangement 53a in the particle beam microscope in FIG. 2.

The scintillator arrangement 201c once again comprises a first and a second scintillator having a first scintillator body 203c and a second scintillator body 205c. The two scintillator bodies 203c, 205c have a configuration corresponding to that of the scintillator bodies 203, 205 of the embodiment in FIG. 4. In contrast to the embodiment in FIG. 4, the scintillator body 203c in FIG. 6 is optically coupled to a surface 231 of the light guide 233 via a short distance. The light guide 233 can be for example the light guide 103 from FIG. 2 or the light guide 73 from FIG. 1.

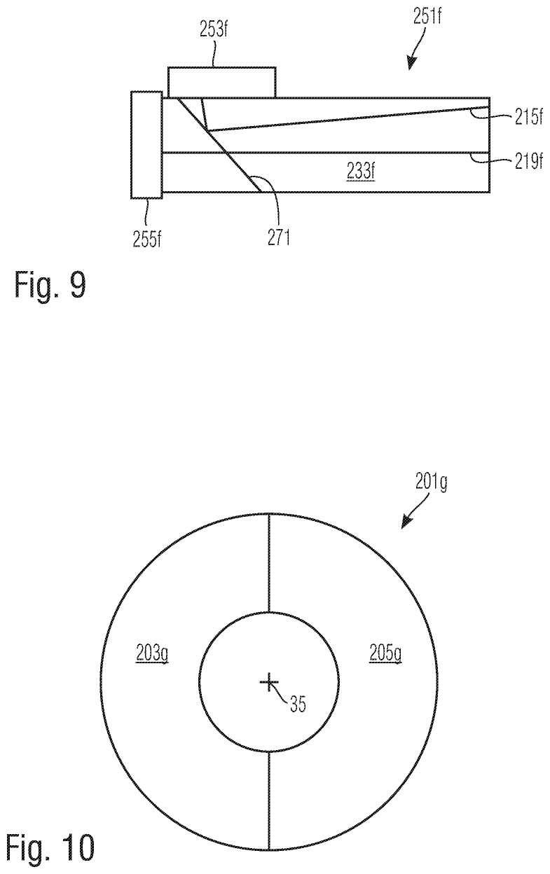

FIG. 6 shows exemplary trajectories-corresponding to FIG. 4—of electrons and generated light, namely of an electron 213c which arrives from the object and generates light 215c at an interaction location 214c, which light emerges from the scintillator body 203c and enters the light guide 233 optically coupled to the scintillator body 203c, at the inner walls of which light guide the light is reflected one or more times in order to reach a light detector arrangement, which is not illustrated in FIG. 6 and is explained below in association with FIGS. 8 and 9. Furthermore, at an interaction location 218c in the scintillator body 205c, light 219c is generated from an electron 217c arriving from the object, which light emerges from the scintillator body 205c, enters the scintillator body 203c, passes through the latter and enters the light guide 233. After single or multiple reflection at the inner walls of the light guide, the light 219c can then be detected by the light detector arrangement.

In the case where the scintillator arrangement 201c from FIG. 6 is used as the second scintillator arrangement 53a in the particle beam microscope 1a in FIG. 2, the following condition should be met: The spectral distribution of the light passing from the first scintillator arrangement 51a to the scintillator arrangement 201c ought to be of substantially longer wavelength than the spectral distribution of light emitted by elements of the second scintillator arrangement 201c. The elements of the second scintillator arrangement 201c are the scintillator bodies 203c and 205c. Meeting this condition substantially prevents light generated by electrons in the first scintillator arrangement 51a from being converted in terms of its spectral distribution by elements of the second scintillator arrangement 201c such that it would appear as though it had been generated by electrons in the second scintillator arrangement 201c. There are various possibilities for achieving this. Either the spectral distribution of the light emitted by the first scintillator arrangement 51a can be of substantially longer wavelength than the spectral distributions of the light emitted by the elements of the second scintillator arrangement 201c, and/or a wavelength shifter and/or a filter above the first scintillator 51a can ensure that the condition is met. Corresponding designs can also apply to other embodiments which include detector arrangements according to the particle beam microscope from FIG. 2: The spectral distributions passing from the first scintillator arrangement 51a to the second scintillator arrangement 53a can be of substantially longer wavelength than the spectral distributions of the light emitted by the second scintillator arrangement 53a.

FIG. 7 is a schematic sectional view of an arrangement comprising a light guide 233d and a scintillator arrangement 201d, substantially corresponding to FIG. 5, which can be used for example as the second scintillator arrangement 53 in the particle beam microscope in FIG. 1 and as the second scintillator arrangement 53a in the particle beam microscope in FIG. 2.

The scintillator arrangement 201d once again comprises a scintillator having a scintillator body 223d and a wavelength shifter 225d. The scintillator body 223d and the wavelength shifter 225d have a configuration substantially corresponding to that of the scintillator body 223 and the wavelength shifter 225 in the embodiment in FIG. 5. In contrast to the embodiment in FIG. 5, the wavelength shifter 225d in FIG. 7 is optically coupled to a surface 231d of the light guide 233d via a short distance. The light guide 233d can once again be the light guide 73 from FIG. 1, for example.

The scintillator arrangement 201d furthermore comprises an annular spacer 241, which is inserted alongside the wavelength shifter 225d between the scintillator body 223d and the light guide 233d. In other embodiments, the spacer 241 can for example also be replaced by vacuum or be obviated by virtue of the scintillator body 223d in this region being in direct contact with the surface 231d of the light guide 233d. The elements of the scintillator arrangement 201d are accordingly the scintillator body 223d, the wavelength shifter 225d and, if present, the spacer 241.

In other exemplary embodiments, the position of wavelength shifter 225d and spacer 241 is interchanged, wherein the wavelength shifter 225d can be embodied as a narrow ring whose area occupies one fifth or less in comparison with the area of the spacer 241.

FIG. 7 shows exemplary trajectories-corresponding to FIG. 5—of electrons and generated light, namely those of an electron 213d which arrives from the object and generates light 215d having the first spectral distribution at an interaction location 214d, which light emerges from the scintillator body 223d, passes through the spacer 241 and enters the light guide 233d in order to be guided to a light detector arrangement. Furthermore, at an interaction location 218d in the scintillator body 223d, light 221d having the first spectral distribution is generated from an electron 217d arriving from the object, which light emerges from the scintillator body 223d and enters the wavelength shifter 225d. At an interaction location 222d in the wavelength shifter 225d, the light having the first spectral distribution is converted into light 219d having the second spectral distribution, which light leaves the wavelength shifter 225d and enters the light guide 233d. The spacer 241 can be embodied as an optical filter which trims the light having the first spectral distribution in a spectral range in which the first and second spectral distributions overlap one another. Better signal separation can be achieved as a result.

FIG. 8 shows a schematic view of a light detector arrangement 251, which can be used for example as the first light detector arrangement 55 or the second light detector arrangement 57 in the particle beam microscope in FIG. 1 or the light detector arrangement 101 in the particle beam microscope in FIG. 2. The light detector arrangement 251 comprises a first light detector 253 for detecting light 215e having the first spectral distribution and a second light detector 255 for detecting light 219e having the second spectral distribution. For this purpose, the light detector arrangement 251 comprises a first light guide 257, which is optically coupled to one part of an end 259 of the light guide 233e and guides to the first light detector 253 light which emerges from the light guide 233e through this part of the end 259 of this light guide 233e. In the beam path between the light guide 257 and the first light detector 253, a first optical filter 261 is provided, which allows light having the first spectral distribution to pass to the first light detector 253 better than light having the second spectral distribution.

The light detector arrangement 251 furthermore comprises a second light guide 263, which is optically coupled to another part of the end 259 of the light guide 233e and guides to the second light detector 255 light which emerges from the light guide 233e through this other part of the end 259 of this light guide 233e. In the beam path between the light guide 263 and the second light detector 255, a second optical filter 265 is provided, which allows light having the second spectral distribution to pass to the second light detector 255 better than light having the first spectral distribution. On account of the arrangement of the optical filters 261 and 265 in the beam path towards the first light detector 253 and the second light detector 255, respectively, it is possible to selectively detect the two kinds of light having the first and the second spectral distribution, respectively, using the two light detectors 253, 255.

In this case, the cut-off frequencies of the optical filters 261 and 265 are tuned to the spectral distributions of the light emitted by the scintillator bodies and optionally also by the wavelength shifter of the scintillator arrangements with which the light detector arrangement is jointly used. If a further optical filter is contained in the light-optical beam path, then this is likewise tuned to the cut-off frequencies of the optical filters 261 and 265.

FIG. 9 is a schematic view of a light detector arrangement in accordance with a further embodiment similar to FIG. 8. The light detector arrangement 251f also comprises a first light detector 253f for detecting light 215f having the first spectral distribution and a second light detector 255f for detecting light 219f having the second spectral distribution.

In the beam path towards the two light detectors 253f and 255f, in the light guide 233f a dichroic beam splitter 271 is provided, which reflects the light 215f having the first spectral distribution towards the first light detector 253f, while it allows the light 219f having the second spectral distribution to pass through towards the second light detector 255f. Consequently, the dichroic beam splitter 271 in a way fulfils the functions of the first optical filter 261 and the second optical filter 265 of the light detector arrangement 251 in FIG. 8. In order to further improve the discrimination of the signals, the optical filter 261 from FIG. 8 can be arranged in the beam path between the dichroic beam splitter 271 and the light detector 253f, or/and the optical filter 265 from FIG. 8 can be arranged in the beam path between the dichroic beam splitter 271 and the light detector 255f.

Like FIG. 3, FIG. 10 is a bottom view of a scintillator arrangement 201g, which is likewise usable as a scintillator arrangement, for example as the first scintillator arrangement 51 or the second scintillator arrangement 53 in the particle beam microscope 1 in FIG. 1, or as the first scintillator arrangement 51a or the second scintillator arrangement 53a in the particle beam microscope 1a in FIG. 2. The scintillator arrangement 201g comprises a first scintillator having a first scintillator body 203g, which in the bottom view in FIG. 10 has the shape of an annulus, similar to the scintillator body 203 in FIG. 4 or the scintillator body 203c in FIG. 6. The scintillator arrangement 201g furthermore comprises a second scintillator having a second scintillator body 205g, which covers a part of the scintillator body 203g in the bottom view in FIG. 10. In contrast to the embodiments in FIGS. 4 and 6, however, the second scintillator body 205g does not have the shape of an annulus, but rather the shape of an annulus segment covering the right-and half of the annular first scintillator body 203g. With regard to the generation of light having a first spectral distribution and a second spectral distribution from electrons arriving from the object, the scintillator arrangement 201g corresponds to the scintillator arrangements in FIGS. 4 and 6. On account of the different geometry of the second scintillator arrangement 205g in comparison with the scintillator arrangements in FIGS. 4 6, the scintillator arrangement 201g enables electrons to be discriminated with regard to their emission direction in a circumferential direction around the principal axis 35 of the objective lens 7. For example, the scintillator arrangement 201g enables the object to be imaged simultaneously from two different viewing directions.

It is possible to modify the scintillator arrangement 201g with regard to the implementation of a scintillator arrangement with a wavelength shifter according to the embodiments in FIGS. 5 and 7 by way of the wavelength shifter being embodied as an annulus segment arranged on a scintillator body having the shape of an annulus.

Each of the light detector arrangements 55 and 57 in FIG. 1 and the light detector arrangement 101 in FIG. 2 can be configured to discriminate light having different spectral distributions by virtue of a plurality of light detectors being used in the respective light detector arrangement, for example, wherein wavelength-selective elements such as optical filters or dichroic beam splitters, for example, are arranged in the beam paths towards these light detectors. Besides the two different spectral distributions explained above, three or more spectral distributions that differ from one another in pairs can be detected in a discriminated manner.

In the example in FIG. 2, the first scintillator arrangement 51a can comprise one or more scintillator bodies composed of the same scintillator material, which each generate light having an identical first spectral distribution. Alternatively, the second scintillator arrangement 53a can comprise one or more scintillator bodies composed of the same scintillator material, which each generate light having an identical second spectral distribution different from the first spectral distribution. Furthermore, the first scintillator arrangement 51 in FIG. 1 and the first scintillator arrangement 51a in FIG. 2 can each comprise a plurality of scintillator bodies which generate light having spectral distributions that differ from one another in pairs. Alternatively, the second scintillator arrangement 53 in FIG. 1 and the second scintillator arrangement 53a in FIG. 2 can each comprise a plurality of scintillator bodies which generate light having spectral distributions that differ from one another in pairs.

1. A particle beam microscope, comprising:
a particle beam source configured to generate a particle beam;
an objective lens configured to focus the particle beam in an object plane;
a first scintillator configured to generate light from electrons arriving from the object plane;
a second scintillator configured to generate light from electrons arriving from the object plane; and
a light detector configured to detect light generated by the first scintillator and light generated by the second scintillator,
wherein:
a first beam path of the light generated by the first scintillator between the first scintillator and the light detector and a second beam path of the light generated by the second scintillator between the second scintillator and the light detector partly overlap one another;
the first scintillator comprises a first scintillator body comprising a first scintillator material configured to generate light having a first spectral distribution from electrons;
the second scintillator comprises a second scintillator body comprising a second scintillator material configured to generate light having a second spectral distribution from electrons; and
the second spectral distribution is different from the first spectral distribution.

2. The particle beam microscope of claim 1, wherein:
along a principal axis of the objective lens, a smallest distance between the first and second scintillator bodies is less than 10 mm; and
in the direction of the principal axis, the first scintillator body comprises a surface region which does not overlap the second scintillator body.

3. The particle beam microscope of claim 1, wherein:
in a direction of the principal axis of the objective lens, the first scintillator body does not overlap the second scintillator body;
the first scintillator body is substantially outside the second beam path, and
the second scintillator body is substantially outside the first beam path.

4. The particle beam microscope of claim 1, wherein:
in a direction of a principal axis of the objective lens, a first part of the first scintillator body overlaps the second scintillator body; and
the first part of the first scintillator body is within a beam path of the light generated by the second scintillator between the second scintillator and the light detector.

5. The particle beam microscope of claim 4, wherein a surface of the second scintillator body is optically coupled to a surface of the first scintillator body.

6. The particle beam microscope of claim 5, further comprising a light guide in which the first and second beam paths overlap one another, wherein a surface of the first scintillator body is optically coupled to a surface of the light guide.

7. The particle beam microscope of claim 1, wherein the first scintillator body has a shape of an annulus, and/or the second scintillator body has a shape of an annulus.

8. The particle beam microscope of claim 1, wherein the first scintillator body has a shape of an annulus segment, and/or the second scintillator body has a shape of an annulus segment.

9. The particle beam microscope of claim 1, wherein:
a centroid of the first spectral distribution is at a first wavelength;
a centroid of the second spectral distribution is at a second wavelength, and
an absolute value of a difference between the first wavelength and the second wavelength is greater than 50 nm.

10. The particle beam microscope of claim 9, wherein the first wavelength is less than the second wavelength.

11. The particle beam microscope of claim 9, further comprising an optical filter arrangeable in the first beam path, wherein the optical filter is configured allow the light having the first spectral distribution to pass to the light detector better than the light having the second spectral distribution.

12. The particle beam microscope of claim 9, wherein:
the light detector comprises a first light detector configured to detect the light having the first spectral distribution and a second light detector configured to detect the light having the second spectral distribution;
the second light detector is different from the first light detector;
a first optical filter is in the first beam path and allows the light having the first spectral distribution to pass to the first light detector better than the light having the second spectral distribution; and
a second optical filter is arranged in the second beam path and allows the light having the second spectral distribution to pass to the second light detector better than the light having the first spectral distribution.

13. The particle beam microscope of claim 12, further comprising a dichroic beam splitter defining the first and second optical filters.

14. The particle beam microscope of claim 1, wherein the scintillator body of the scintillator has a shape of an annulus, and/or the wavelength shifter has a shape of an annulus.

15. The particle beam microscope of claim 1, wherein the scintillator body of the scintillator has a shape of an annulus, and/or the wavelength shifter has a shape of an annulus segment.

16. A particle beam microscope, comprising:
a particle beam source configured to generate a particle beam;
an objective lens configured to focus the particle beam in an object plane;
a scintillator configured to generate light from electrons arriving from the object plane, the scintillator comprising a scintillator body comprising a scintillator material configured go generate light having a first spectral distribution from electrons;
a wavelength shifter configured to convert the light generated by the scintillator into light having a second spectral distribution; and
a light detector configured to detect light generated by the scintillator and light generated by the wavelength shifter,
wherein:
a first beam path is between a first part of the scintillator body and the light detector; and
the wavelength shifter is substantially outside the first beam path.

17. The particle beam microscope of claim 16, wherein no wavelength shifter is provided in the first beam path.

18. The particle beam microscope of claim 16, wherein a surface of the wavelength shifter is optically coupled to a surface of a second part of the scintillator body.

19. The particle beam microscope of claim 16, wherein the first beam path and a second beam path of the light converted by the wavelength shifter between the wavelength shifter and the light detector partly overlap one another.

20. The particle beam microscope of claim 19, further comprising a light guide in which the first beam path and the second beam path overlap one another, wherein the surface of the wavelength shifter is optically coupled to a surface of the light guide.

21.-27. (canceled)
